(19) United States
(12) Patent Application Publication
(10) Pub. No.: US 2024/0006784 A1
(43) Pub. Date: Jan. 4, 2024

(54) INTERPOSER WITH CONTACT RETENTION WITH HEAT STAKE

(71) Applicant: Amphenol Corporation, Wallingford, CT (US)

(72) Inventor: Paul R. Taylor, Mechnicsburg, PA (US)

(73) Assignee: Amphenol Corporation, Wallingford, CT (US)

(21) Appl. No.: 18/344,110

(22) Filed: Jun. 29, 2023

Related U.S. Application Data
(60) Provisional application No. 63/357,540, filed on Jun. 30, 2022.

(51) Int. Cl. H01R 9/22; H01R 31/06; H01L 23/50

(52) U.S. Cl. CPC H01R 9/223; H01R 31/06; H01L 23/50

(57) ABSTRACT

A low profile interposer with multiple electrical contacts held in a housing via a process, such as heat staking, that deforms portions of the housing into protuberances that lock the electrical contacts within openings of the housing. The contacts may be arranged in multiple parallel columns and may have an elongated dimension that is aligned at an acute angle with respect to the column direction. Distal tips of the contact portions of the electrical contacts may be bent to extend into an opening in the housing, even when the electrical contact is in an uncompressed state.

### RELATED APPLICATIONS

This application claims the benefit of U.S. Provisional Application Ser. No. 63/357,540, filed on Jun. 30, 2022, under Attorney Docket No. A1245.70005US00 and entitled “INTERPOSER WITH CONTACT RETENTION WITH HEAT STAKE,” which is incorporated by reference herein in its entirety.

### BACKGROUND

This patent application relates generally to interconnection systems, such as those including electrical connectors, used to interconnect electronic assemblies.

Electrical connectors are used in many electronic systems. It is generally easier and more cost effective to manufacture a system as separate components that are electrically connected through separable interfaces. With separable interfaces, the components may be separately manufactured and then simply assembled into an overall system. In use, components can be added or replaced in the electronic system, such as to replace a defective component or to enable higher-performing components to be added to the system such that the electronic system is upgraded.

In some instances the components are themselves subassemblies, which are often manufactured by connecting semiconductor devices and other components to a printed circuit board (PCB). The electronic systems may then be assembled by joining the subassemblies. Two-piece connectors are often used for this purpose, with one piece of the connector being mounted on the PCB's of each of two subassemblies to be joined. The subassemblies are joined by mating one piece of the connector with the other.

Components may also be joined through interposers. An interposer has one or more separable interfaces. A separable interface that mates with a component may have a planar array of compliant contacts. A component may be mated to the interposer by pressing the component against the compliant contacts. For example, a semiconductor device, such as a processor chip, may have an array of pads or other conductive structures on a surface. The pads may be aligned with the compliant contacts such that pressing the device against the interposer makes connections between the compliant contacts and the pads or other conductive structures.

Each of the compliant contacts may extend through the interposer to an opposite surface at which a second end of the contact is connected to a second component. In many system architectures, that second component may be a PCB, which may also include an array of pads to which the second ends of the contacts of the interposer are connected. Those connections may be made through compliant contacts on the second ends of the contacts, forming a separable interface. Though, in some interposers, the second end is fixed to a second component, such as via soldering to a PCB.

Interposers may be used in combination with mechanical components that urge one or more components towards separable interface(s) of the interposer. An interposer that connects a semiconductor chip to a PCB, for example, may be used in combination with components that press the semiconductor chip towards a separable interface of the interposer. If the interposer is connected to the PCB through a separable interface, the mechanical components may also press the interposer against the PCB so that the compliant contacts facing the PCB generate sufficient force to make connections to the PCB.

Interposers may be low profile, meaning that they have a low height in a direction perpendicular to the surfaces of the components that are connected through the interposer. Known interposers, for example, may have a height on the order of 1 mm and may contribute to the miniaturization of electronic devices. Interposers, however, may not be made arbitrarily small, as they must simultaneously meet multiple other requirements, such as sufficient mechanical strength, ease of manufacture with sufficient precision, generation of an appropriate contacting force, and contacts in a pattern that aligns with the pads or other conductive structures joined through the interposer.

### SUMMARY

This application describes an interposer and a method of manufacturing an interposer.

In one aspect, concepts described herein may be embodied as an interposer, comprising an insulative member comprising a first surface, a second surface parallel to the first surface, and a plurality of openings through the insulative member, the insulative member further comprising a shelf and a protuberance within each the plurality of openings; and a plurality of electrical contacts disposed within respective openings of the plurality of openings, each electrical contact of the plurality of electrical contacts comprising a base, a first contact portion extending from the base toward the first surface and a second contact portion extending from the base toward the second surface. For each electrical contact of the plurality of electrical contacts, the base may be captured between a shelf and a protuberance within a respective opening of the plurality of openings.

Concepts as described herein may be embodied as an interposer, comprising an insulative member comprising a first surface, a second surface parallel to the first surface, and a plurality of openings through the insulative member; and a plurality of electrical contacts disposed within respective openings of the plurality of openings, each electrical contact of the plurality of electrical contacts comprising a base, a first contact portion extending from the base toward the first surface and a second contact portion extending from the base toward the second surface. For each electrical contact of the plurality of electrical contacts: the base of the electrical contact is between a first portion of the insulative member and a second portion of the insulative member; the first portion of the insulative member is between the electrical contact and the first surface; the second portion of the insulative member is between the electrical contact and the second surface; and the insulative member comprises a void between the first portion and the first surface adjacent a respective opening of the plurality of openings for the electrical contact.

Concepts as described herein may also be embodied as interposer comprising an insulative housing comprising: a first surface and a second surface parallel to the first surface; a plurality of openings arranged in an array and extending between the first surface and the second surface, each of the plurality of openings being bounded by a surface and comprising a groove in the surface; and a plurality of electrical contacts, each disposed within a respective opening of the plurality of openings and comprising a U-shaped base, a first beam extending from the U-shaped base, a second beam extending from the U-shaped base and an extension extending from the electrical contact. For each of the plurality of electrical contacts the extension of the electrical contact extends into the groove of the respective opening and the electrical contact is heat staked within the respective opening.

Concepts as described herein may also be embodied as a method of manufacturing an interposer comprising a plurality of electrical contacts held within an insulative member comprising a plurality of openings, wherein the plurality of electrical contacts each comprises a base, a first contact portion extending from the base and a second contact portion extending from the base. The method may comprise inserting the plurality of electrical contacts into respective openings in the insulative member such that the base of each of the plurality of electrical contacts is adjacent a shelf within a respective opening, and deforming the insulative member adjacent each of the respective openings to form a protuberance that locks the base of each of the electrical contact in the respective opening between the protuberance and the shelf.

Concepts as described herein may also be embodied as a method for manufacturing an interposer, comprising: stamping at least an electrical contact in a sheet of conductive metal defining a plane, wherein the electrical contact comprises a base and a contact portion comprising a beam extending from the base; bending the base portion into a U-shape; bending the contact portion away from the plane; inserting the electrical contact with into an opening of a housing; and locking the base of the electrical contact into place by heat staking.

Concepts as described herein may also be embodied as a method for manufacturing an interposer, comprising: stamping from a sheet of metal at least an electrical contact with a U-shaped base and a first contact portion comprising a beam extending from the U-shaped base and a second contact portion comprising a beam extending from the U-shaped base; bending the first contact portion and the second contact portion away from a plane encompassing the U-shaped base in opposite directions such that a distal end of the first contact portion and a distal end of the second contact portion are separated in a direction perpendicular to the plane; inserting at least the U-shape base into an opening of a housing; and locking the electrical contact into the opening by heat staking.

The foregoing features may be used separately or in any suitable combination. The foregoing is a non-limiting summary of the invention, which is defined by the attached claims.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is an exploded view of an illustrative electronic assembly including an interposer disposed between two printed circuit boards, in accordance with some embodiments;

FIG. 2 is a perspective view of a separable interface of an illustrative interpose with an array of electrical contacts in respective openings in a surface of the interposer, in accordance with some embodiments;

FIG. 3A is a plan view of a column with a plurality of electrical contacts stamped from a sheet of conductive metal, in accordance with some embodiments;

FIG. 3B is a plan view of an electrical contact of an interposer with tapered beams, showing multiple regions with different strain when the electrical contact is compressed, in accordance with some embodiments;

FIG. 3C is a side view of an illustrative electrical contact of FIG. 3B with two contact portions bent separately, in accordance with some embodiments;

FIG. 3D is a front view of an electrical contact of FIG. 3B disposed in an opening of a housing of an interposer with two contact portions extending from the housing with tips of the two contact portions bent separately towards the housing, in accordance with some embodiments.

FIG. 4A illustrates a plurality of electrical contacts aligned with respective openings of an illustrative interposer, such as may occur during a step of an illustrative manufacturing process of an interposer in accordance with some embodiments;

FIG. 4B is an enlarged view of a portion of the illustrative interposer of FIG. 4A, in accordance with some embodiments;

FIG. 5A is an isometric view of the illustrative interposer of FIG. 4A with the electrical contacts inserted into respective openings, such as may occur at a later step of the illustrative manufacturing process in accordance with some embodiments;

FIG. 5B is an isometric view of the illustrative interposer of FIG. 5A with the electrical contacts locked into respective openings with heat staking, such as may occur at a later step of the illustrative manufacturing process in accordance with some embodiments;

FIG. 5C is an enlarged view of a void formed from heat staking in the illustrative interposer of FIG. 5B, in accordance with some embodiments;

FIG. 6A is a plan view of a plurality of electrical contacts stamped in a sheet of conductive metal, in accordance with some embodiments;

FIG. 6B is an isometric view of a plurality of electrical contacts formed from the sheet of FIG. 6A, in accordance with some embodiments;

FIG. 7 is a side view of an illustrative interposer with a plurality of electrical contacts formed as illustrated in FIGS. 6A and 6B in respective openings, in accordance with some embodiments;

FIG. 8A is an isometric view of an opening of an interposer housing configured to receive an electrical contact formed as illustrated in FIGS. 6A and 6B, in accordance with some embodiments;

FIG. 8B is an isometric view of the opening of the illustrative interposer of FIG. 8A with an electrical contact formed as illustrated in FIGS. 6A and 6B pressed into the opening, in accordance with some embodiments;

FIG. 8C is an isometric view of the opening of the illustrative interposer of FIGS. 8A-8B at a later stage of manufacture with the electrical contact locked into the opening with heat staking, in accordance with some embodiments;

FIG. 8D is a side view of the electrical contact in the locked state shown in FIG. 8C, in accordance with some embodiments;

### DESCRIPTION OF PREFERRED EMBODIMENTS

The inventors have recognized and appreciated techniques that enable simple and reliable manufacture of a very low profile interposer. Techniques as described herein may enable construction of an interposer with a height of less than 1 mm, and less than 0.5 mm in some embodiments. The interposer may nonetheless generate an appropriate amount of contact force that reliable connections may be formed to a component pressed against a separable interface of the interposer. Electrical contacts may be dual compression contacts, such that the interposer may have two separable interfaces on opposing sides of an interposer housing.

Techniques as described herein may also enable construction of an interposer with a separable interface, or in some implementations two opposing separable interfaces, with contact points separated by less than 0.7 mm in at least one dimension. In some examples, the contact points may be arranged in a rectangular array with separation between two contact points in each of two dimensions of less than 0.7 mm. The arrays of contact points, for example, may be square arrays and the contact points may be spaced on a pitch of approximately 0.65 mm, or less in some examples.

An interposer may be formed by inserting a plurality of electrical contacts into respective openings of a housing. The plurality of electrical contacts may be stamped from a sheet of conductive metal. The contacts may then be formed into a three-dimensional shape and inserted into respective openings of the housing. The electrical contracts may be locked in the openings by heat staking. Features on the electrical contacts may engage with the housing to hold the contacts in place before they are heat staked. These features, for example, may provide a more precise positioning of the contact points of the array of contact points, enabling the pads of a component in contact with the separable interface to be smaller, while ensuring reliable connections through the interposer.

Heat staking may capture a base of each electrical contact within an opening in the interposer housing. Compliant portions of the contact may be free to move within the opening. Such a structure may enable deflection of the electrical contact over a large percentage of the length of the contact and/or may enable spring energy to be stored in the base of the contact when the contact is compressed. As a result, the electrical contacts may generate a desired amount of contact force, even if shorter than an electrical contact in which the base of the electrical contact is embedded in a housing of the interposer.

In some examples, heat staking may result in asymmetrical protuberances locking an electrical contact into the interposer housing. For example, a protuberance may be formed on only one side of the electrical contact. For a dual compression contact, such an asymmetrical locking arrangement may enable the contact to rotate during compression, if the forces on each side of the contact are unbalanced. Such rotation may tend to equalize the forces generated by the two beams of the dual compression contact, equalizing the contact force at each of two separable interfaces of the interposer.

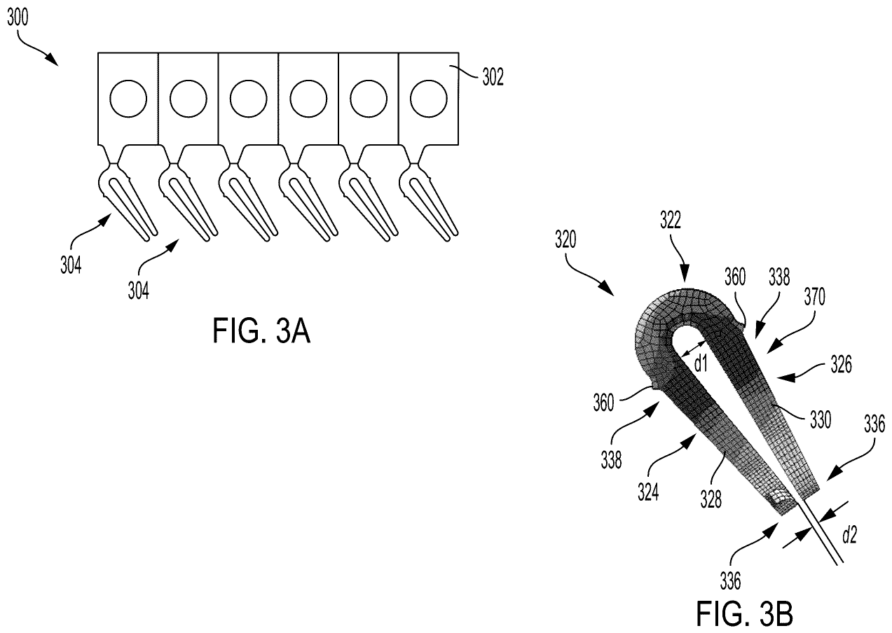

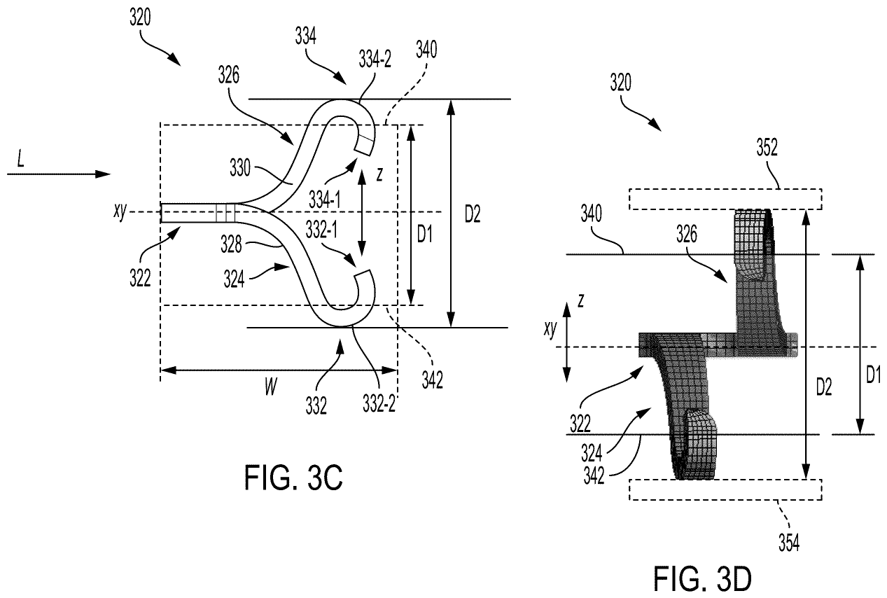

In some embodiments of a dual compression contact, each of the electrical contacts of an interposer may have a U-shaped base and two contact portions each extending from the U-shaped base. For example, FIGS. 3B and 3C illustrate an electrical contact having a U-shaped base extending in a plane, and two beams that extend from the U-shaped base and away from the plane so that the distal ends of the beams are separated. Once the electrical contacts are formed, they may be inserted into respective openings of the interposer to each rest on a shelf in the inner wall of the respective openings. For each electrical contact, heat staking may be used to form a protuberance on top of the electrical contact base to lock the electrical contact in place. The protuberance may be formed, for example, with a heated punch that presses on a thermoplastic housing over an edge of the inner wall of the respective opening near the base of the electrical contact.

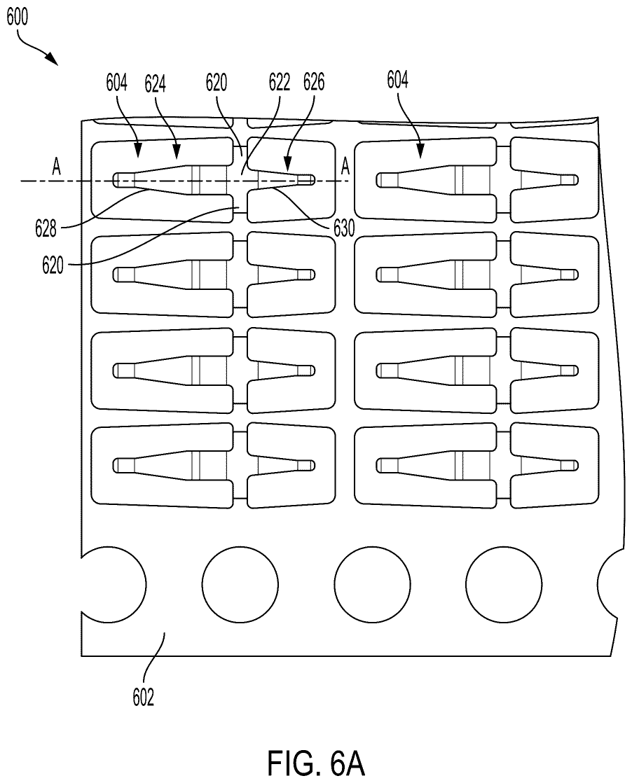

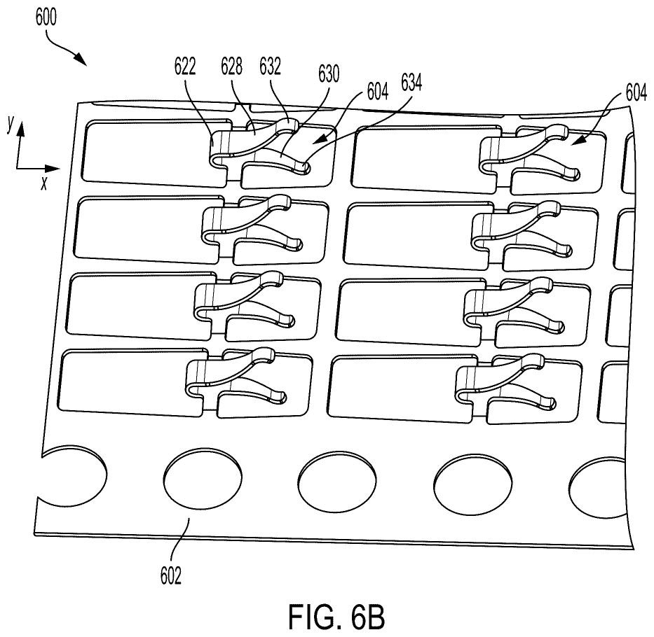

U-shaped contacts may be manufactured in the shape illustrated in FIGS. 3B and 3C by stamping the U-shaped portion from a sheet of metal. Such an approach may enable a tight radius on the U-shaped portion of the contact. In some embodiments, a U-shaped portion of the electrical contact may be manufactured by stamping a contact blank, including two contact portions, from a sheet of metal and then bending a radius into the contact blank to form a U-shaped portion. For example, FIGS. 6A-6B illustrate electrical contacts stamped from a sheet of conductive metal and each bent to have a U-shaped portion. Two contact portions of each of the electrical contacts are formed to extend from the U-shaped portion and away from the plane of the sheet of conductive metal so that the distal ends of the contact portions are separated. Each of the electrical contacts may have an engagement feature. For example, the base of an electrical contact may include one or more projections. A projection may be an extension extending perpendicularly from the centerline of the electrical contact such that, when the electrical contact is inserted in a respective opening of the housing of the interposer, at least the extension(s) of the base rest on respective shelves in corresponding grooves in the inner wall of the respective opening and engage with the corresponding groove(s). The extension(s) may further engage with the corresponding grooves so that the electrical contact temporarily stays in the respective opening after being inserted therein. Heat staking may be used to form a protuberance on top of each of at least the extension portion of the base, so that the base is captured between the shelf and the protuberance and the electrical contact is locked in place.

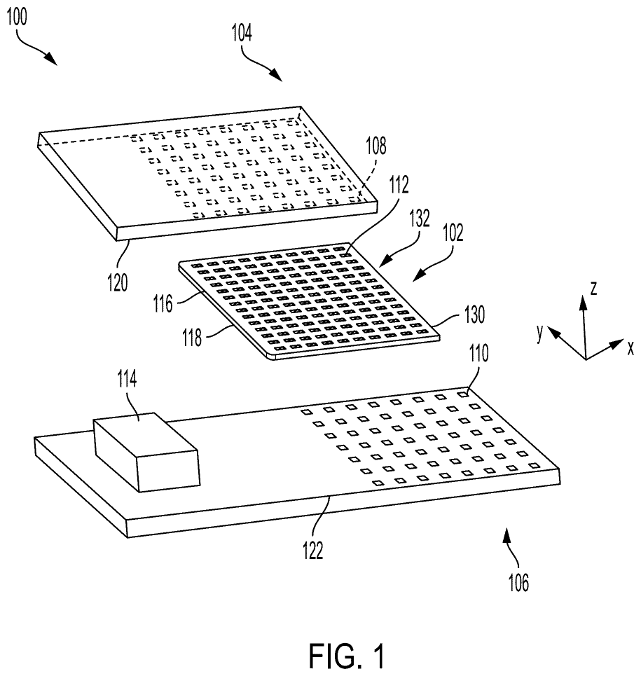

FIG. 1 is an exploded view of an illustrative electronic assembly including an interposer disposed in between two components, which in this example are illustrated as two printed circuit boards. Here, electronic assembly 100 is shown with substrates 104 and 106, an interposer 102 between the substrates and semiconductor devices and other components attached to the substrates, of which component 114 is an example. Substrates 104 and 106 may be part of respective electronic components, implemented in this example as subassemblies including other electronic components. For example, substrate 106 may be a motherboard and substrate 104 may be a daughter card (e.g., a processor card).

In the example of FIG. 1, electronic assembly 100 is shown to have a mezzanine or stacking configuration, such that the electrical interface of substrate 106 is in a plane parallel to the plane of the electrical interface of substrate 104. In the example of FIG. 1, substrate 104 includes pads 108 formed on the bottom surface 120 of substrate 104, and substrate 106 includes pads 110 formed on the top surface 122 of substrate 106, where the bottom surface of substrate 104 is parallel to the top surface of substrate 106. The pads of each of the substrates 104, 106 may be connected via traces or other conducting structures within the substrates to semiconductor chips, such as electronic component 114, or other components mounted on the substrates.

In this example, the pads of the electrical interfaces on both substrate 104 and substrate 106 have a similar configuration, each with an array of pads. The pads within each array may be closely spaced, leading to miniaturization of electronic assembly 100. An interposer as described herein enables the pads to be spaced, center to center, by less than 1 mm in at least one dimension. The pads, for example, may be arranged in an array with multiple parallel columns of pads. The pads within a column may have a center to center spacing of less than 1 mm, or less than 0.7 mm or between 0.4 and 0.7 mm, such as about 0.65 mm, in some examples. The columns may have a center to center spacing of less than 1 mm, or less than 0.7 mm or between 0.4 and 0.7 mm, such as about 0.65 mm, in some examples. In this example, the array of pads is a square array.

During operation, pads 108 are in electrical contact with pads 110 via interposer 102. In this example, interposer 102 has dual compression contacts, with contact portions of each contact making contact with a pad 108 on the bottom surface 120 of substrate 104 a pad 110 on the top surface 122 of substrate 106. Force to press the contact portions against the corresponding pads is generated by mechanical components of electronic system 100 (not shown in FIG. 1, pressing substrates 104 and 106 together, with interposer 102 between them.

The separation between the substrates, and consequently the height of interposer 102 (along the z-axis), may be small. A small separation may enable high signal speeds between the PCB's and also reduced packaging. The separation, for example, may be 1 mm or less, or less than 0.8 mm, or less than 0.6 mm, or between 0.4 and 0.6 mm, such as approximately 0.5 mm, for example.

With further reference to FIG. 1, the interposer 102 may include a housing 130, a top surface 116, a bottom surface 118 parallel to the top surface, a plurality of openings 132 through the housing 130, and a plurality of electrical contacts 112 in respective openings. The plurality of openings may be arranged in an array and extending between the top surface 116 and the bottom surface 118 of the housing 130. In some embodiments, the housing may be an insulative member, and the plurality of electrical contacts may be made of conductive metal, such as a copper alloy. Phosphor bronze, for example, may be used.

Interposer 102 may be mounted to a substrate, which may be substrate 106 in this example, via mechanical components (not shown). The mechanical components force contact portions of the electrical contacts against the pads 110 on substrate 106. The contact portions may be compliant, such as compliant beams at the bottom side 118 of interposer 102. When interposer 102 is pressed against substrate 106, those beams may be deflected, resulting in spring-loaded contacts. Latching structures (not shown in FIG. 1) may retain interposer 102 in place on substrate 106, generating the force that creates the spring-loaded contacts. Further, substrate 104 may be pressed into the top surface 116 of interposer 102. Interposer 102 or some other components of electronic assembly 100 may include latching structures (not shown in FIG. 1) designed to hold substrate 104 to the interposer and to press the substrate against the contact portions of the interposer contacts. In some embodiments, the upper contact portions of the contacts of the interposer 102 may be compliant and may exert a force against pads 108 when substrate 104 is pressed against the interposer. Similarly, the lower contact portions of the contacts of the interposer 102 may be compliant and may exert a force against pads 110 when substrate 106 is pressed against the interposer.

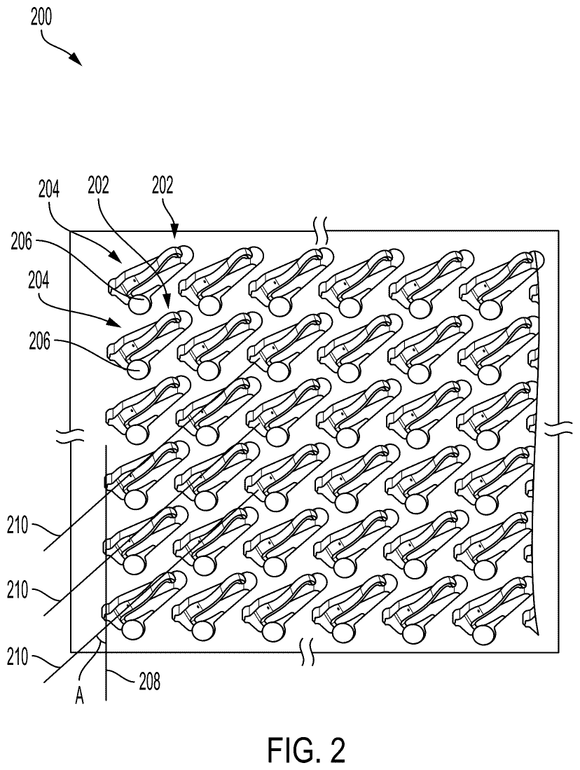

FIG. 2 illustrates an array of electrical contacts in respective openings in an illustrative interposer, in accordance with some embodiments. In some embodiment, interposer 200 may be at least a portion of the interposer 102 shown in FIG. 1, having a plurality of electrical contacts 202 disposed within respective openings of the plurality of openings 204 of a housing of interposer 200. The electrical contacts 202 may be locked into respective openings 204 by protuberances 206. Protuberances 206 may be formed by deforming a portion of the housing of the interposer, which is further described in detail.

In this example, the electrical contacts are arranged in a plurality of parallel columns extending in a column direction 208. Each of the electrical contacts has two beams, both of which are elongated, providing an elongated axis 210 to the contact. In this example, the elongated axes 210 of the contacts are parallel to each other. The elongated axes may make an acute angle, A, with respect the column direction 208. The angle A may be, for example, between 25 degrees and 55 degrees, such as between 30 and 40 degrees or about 35 degrees in some examples. An acute angle may enable the contacts to have compliant beams that generate a desired contacting force while making contact with a tightly packed array of pads on substrates above and below interposer 200.

FIG. 3A is a plan view of a plurality of electrical contacts stamped from a sheet of conductive metal, in accordance with some embodiments. A plurality of electrical contacts 304 may be stamped from a sheet of conductive metal to create a blank 300. Blank 300 may be worked to form contacts with a three-dimensional structure.

FIG. 3B is a plan view of an electrical contact of an interposer. Electrical contact 320 may be any of the plurality of electrical contacts 304 in FIG. 3A. In some embodiments, the electrical contact 320 may be any of the electrical contacts 202 (FIG. 2). The electrical contact 320 may include a base 322 and a first contact portion 324 and a second contact portion 326. The base 322 may be a U-shaped base, which may be stamped from the sheet of conductive metal as described above. Each of the contact portions 324, 326 may include a beam extending from the base 322. For example, contact portion 324 may include beam 328, and contact portion 326 may include beam 330, where beams 328, 330 both extend from the base 322. In the examples of FIGS. 3A and 3B, the base and the beams are integral for each of the electrical contacts. This configuration may result from stamping the contacts from a sheet of conductive metal.

As shown in FIG. 3C, which is a side view of an illustrative electrical contact of FIG. 3B, the contact portions 324, 326 may be bent in opposite directions away from a plane encompassing the base 322 (e.g., plane xy). In such configuration, a distal end 332 of the first contact portion 324 and a distal end 334 of the second contact portion 326 are separated in a direction z perpendicular to the plane (e.g., plane xy). The bending of the contact portions 324, 326 enables contact surfaces 332-2 and 334-2 to be separated by a distance D2. The distance D2 may be greater than the height D1 of a housing of the interposer such that the distal ends of the contact portions to extend respectively through the top and bottom surfaces (e.g., 340, 342) of the housing in which the electrical contract is disposed, in an uncompressed state when the electrical contact is properly installed in the opening of the housing. When the interposer is used, the contact surfaces 332-2 and 334-2 may be in electrical contact with the pads of the substrates that are pressed against the top and bottom surfaces of the interposer (see FIG. 1).

In some embodiments, tips of the distal ends 332-1, 334-1 of the contact portions 324 and 326 may be protected within an opening in the insulative housing of the interposer. In the example of FIGS. 3C and 3D, this configuration is achieved by bending the distal ends 332-1 and 334-1 to curve back towards the xy plane.

Returning to FIG. 3B, in some embodiments, the contact portions 324, 328 may each be tapered. For example, the width of the contact portions near the distal ends 336 may be narrower than the width of the contact portions at proximate ends 338 near the base 322. This configuration enables the electrical contact to store the spring energy more efficiently. For example, when the electrical contact is in electrical contact with a substrate (e.g., 104, 106 of FIG. 1), the tapered beams are pressed down into the interposer. The spring energy stored in the tapered beams will provide better spring force and thus better contact with the substrate(s).

Additionally and/or alternatively, distal ends 336 of the contact portions 324, 326 may be positioned at a closer distance than the proximate ends 338 are positioned. As shown in FIG. 3B, the distance between the distal ends (d2) is smaller than the distance between proximate ends (d1). Having the distal ends of the contact portions of the electrical contacts close enough will enable the pads (e.g., 108, 110 in FIG. 1) in the substrates above and below the electrical contact to be aligned when viewed from a side. For example, as shown in FIG. 3D, in which a pad 352 in the top substrate and a pad 354 in the bottom substrate are aligned perpendicularly to the plane xy that encompasses the base 322. The pads 352, 354 may each be formed on two mating substrates (e.g., PCB boards). Thus, having the distal ends of the contact portions of the electrical contacts closer may enable the pads for the substrates to be connected by the interposer to be aligned in the direction z. Such alignment may simplify design of the interposer and/or may improve high frequency performance of the interposer. The distance between distal ends d2 (see FIG. 3B) may be sufficiently large that the distal ends do not touch each other when the electric contact is compressed between substrates. The configuration shown in FIGS. 3A-3D also result in less metal in each contact portion than conventional interposers such that a lower impedance can be achieved.

Returning to FIG. 3B, additionally, and/or alternatively, the base 322 of the electrical contact 320 may have one or more barbs 360 near the proximate ends 338 of the contact portions (e.g., two barbs with one on each side of the base). The barb(s) 360 may be formed during stamping a sheet of conductive metal to form blank 300 (FIG. 3A). Barbs 360 may result from a feature of a stamping die or may result from progressive die cuts, with barbs 360 formed at the intersection of progressive die cuts. The barb(s) 360 may have sharp tips that bite into the inner wall of the opening in which the electrical contact is inserted with an assembly tool so that the electrical contact stays in the opening when the assembly tool is withdrawn, before heat staking is performed.

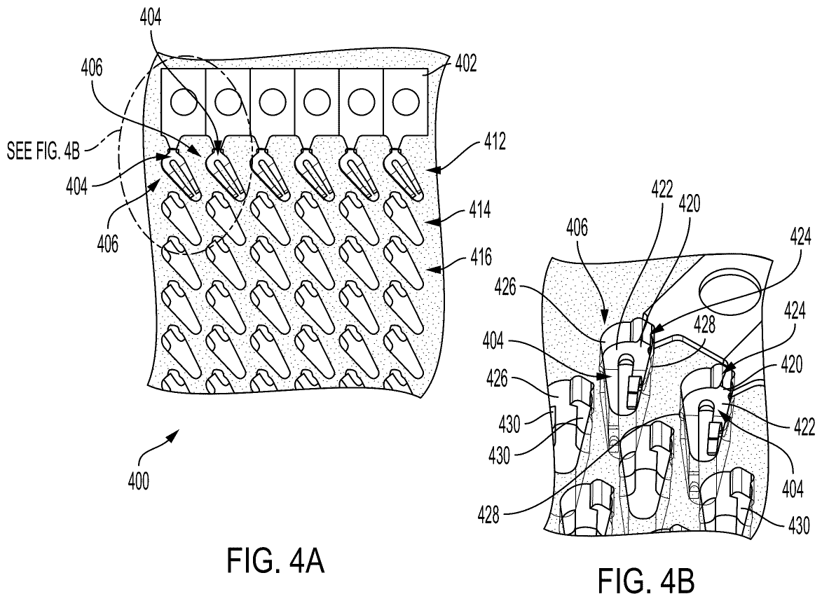

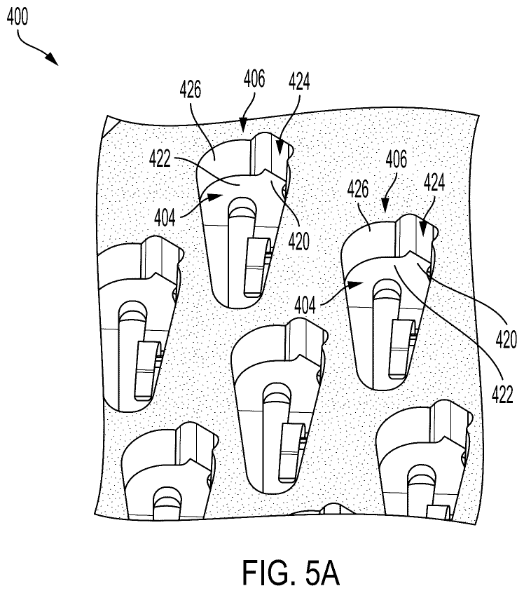

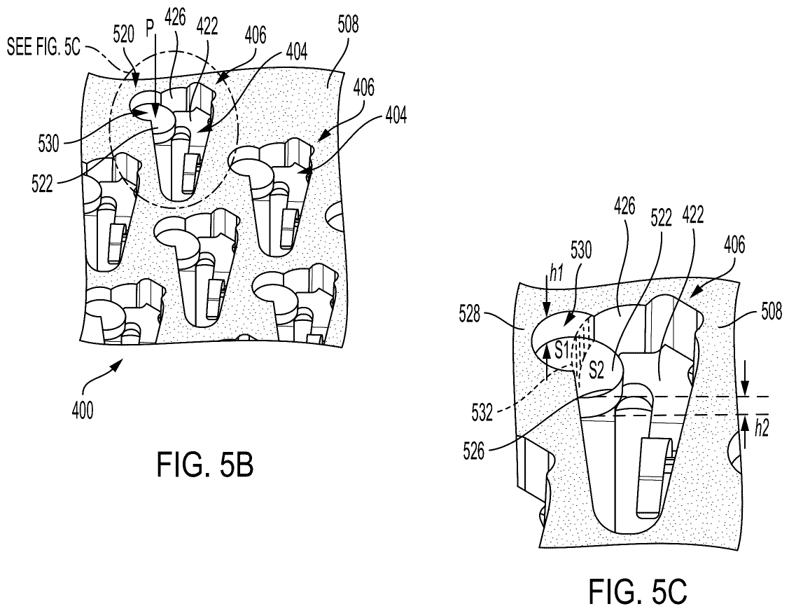

FIGS. 4A, 4B, 5A and 5B illustrate a sequence of steps of an illustrative manufacturing process for an interposer. In this example, the interposer is formed by securing multiple electrical contacts as described above in connection with FIGS. 3A-3D within respective openings in a housing. A plurality of electrical contacts 404 may be stamped for a sheet of conductive metal, in a similar manner as shown in FIG. 3A. The electrical contacts 404 may be manufactured by forming the contacts in blank 300 into three-dimensional shapes with contact portions as described in connection with FIGS. 3C and 3D.

FIG. 4A illustrates a plurality of electrical contacts aligned with respective openings of an illustrative interposer 400 in a stage of an example manufacturing process. The electrical contacts 404 may be held on a carrier. In the example in FIG. 4A, the carrier is a support strip 402 having a plurality of sections spaced in the same spacing of the plurality of openings 406 of the housing of an interposer. Thus, the plurality of electrical contacts 404 may be aligned altogether with a group of openings (e.g., rows 412, 414, 416) of the housing of the interposer with the use of the support strip 402. In the configuration shown in FIG. 4A, the U-shape in the base of each of the electrical contacts, combined with the acute angle as described above, results in a tight spacing (small pitch) among the plurality of electrical contacts in the housing of the interposer.

As shown in FIGS. 4A-4B, each of the plurality of electrical contacts 404 may be connected to the strip support 402 via respective extensions 420, where each extension 420 may extend from the base of a respective electrical contact connecting to a corresponding section of the strip support 402. In some examples, before the electrical contacts are inserted into respective openings of the housing, the electrical contacts connecting to the support strip 402 may be severed therefrom at the extensions of respective bases of the electrical contacts to enable the electrical contacts to be inserted into respective openings of the housing. In other examples, the electrical contacts may be severed from the support strip 402 as they are being inserted into respective openings of the housing.

FIG. 4B illustrates that the housing of the interposer may have shelves 430 within the openings of the housing. An electrical contact may be pressed by a tool into the opening of the housing until it seats on one or more shelves 430 within the opening. The tool may have an edge in a location where the electrical contact is to be separated from support strip 402. In this example, that location is at the end of extension 420. As can be seen in FIG. 4B, which shows support strip 402 with electrical contacts attached, when the contacts are inserted to the desired depth in the openings, the housing interferes with the support strip 402, which is prevented from staying in the same plane as the electrical contacts as the contacts are pressed into the opening. As a result, force of the tool severs the electrical contacts from the support strip 402. Thereafter, the support strip 402 may be removed. Such an operation enables multiple electrical contacts to be inserted into the interposer housing in one cycle of an assembly tool, which may provide efficient assembly of an interposer.

Regardless of how the electrical contact is severed from the support strip, when an electrical contact is severed from the support strip, an extension (e.g., 420) may be formed. When the electrical contact is severed from the support strip, the extension 420 remains extending from the base of the electrical contact. As such, for each of the plurality of electrical contacts, the extension is also integral with other parts of the electrical contract (e.g., the base, the contact portions etc. in FIG. 3B).

The electrical contacts 404, severed from their support strip, are seated within respective openings (e.g., 406). For example, the base 422 of an electrical contact 404 may be pressed against a shelf (such as 430) in the inner wall 426 of the respective opening. The shelf 430 in the inner wall 426 may be integrated with the inner wall in some embodiments. For example, the housing may be molded with the plurality of openings and a respective shelf (or multiple shelves) in the inner wall of each opening. In the configuration shown, each opening 406 of the housing may be bounded by a surface, e.g., inner wall 426, where the inner wall 426 may have a curved segment. The base of the electrical contact 422 may be of a curved edge (e.g., a U-shape) to follow the curved segment of the inner wall of the opening. As shown in FIG. 4B, the extensions 420 may each be engaged with a respective groove 424 of each of the openings in the manner as described above. Extensions may restrain rotation of an electrical contact within an opening.

FIG. 5A is an isometric view of a portion of an illustrative interposer 400 with the electrical contacts inserted into respective openings, in accordance with some embodiments. The illustrative interposer 400 may be implemented as at least a portion of the interposer 102 shown in FIG. 1, in some examples. Interposer 400 may represent a portion of the interposer shown in FIGS. 4A and 4B at a later stage of manufacture. In this example, electrical contacts have been inserted into multiple columns of openings in a housing of the interposer.

As shown in FIG. 5A, a plurality of electrical contacts 404 may have been inserted into respective openings 406 of the housing of the interposer. As shown, each opening 406 of the housing may be bounded by a surface, e.g., inner wall 426. When pressed into a respective opening (e.g., 406), the base 422 of an electrical contact 404 may be pressed against a shelf (such as 430 in FIG. 4B) in the inner wall 426 of the respective opening. Thus, the shelf is underneath the base of the electrical contact and not visible in FIG. 5A. The shelf in the inner wall may be integrated with the inner wall in some embodiments. For example, the housing may be molded with the plurality of openings and a respective shelf (or multiple shelves) in the inner wall of each opening. In some embodiments, the inner wall 426 of each opening may have a curved segment. The base of the electrical contact 422 may be of a curved edge (e.g., a U-shape) to follow the curved segment of the inner wall of the opening.

With further reference to FIG. 5A, each of the electrical contacts 404 may have an engagement feature, which may include, for example, one or more projections that extends from the base 422. Projections may aid in positioning the electrical contact in the housing at one or more phases of manufacture and/or use of the interposer. A projection, such as extension 420, may extend into and engage with an inner wall 426 of the opening 406. For example, the extension 420 may engage with a groove 424 in the inner wall 426. Such a projection may position the electrical contact with respect to the opening and/or may restrain rotation of the electrical contact in use.

Additionally, and/or alternatively, a projection may have other shapes, such as a tab or a barb, and may serve other functions. For example, one or more barbs (see 428 in FIG. 4B, and 360 in FIG. 3B) may have sharp tips that bite into the inner wall 426 of the opening in which the electrical contact is inserted with an assembly tool so that the electrical contact stays in the opening when the assembly tool is withdrawn, before heat staking is performed.

During manufacture, for example, a projection may retain the electrical contact in an opening in the interposer housing. As shown in FIG. 4B, the base 422 of each electrical contact is connected to the support strip 402. An assembly tool may press the electrical contact into a respective opening of the interposer 400, at which time the electrical contacts may have been severed from a support strip. Having the projection of the electrical contact engage with an inner wall of the housing may hold the electrical contact in the opening when the assembly tool is withdrawn. Projections in the form of one or more barbs, such as barbs 428 (or 360 in FIG. 3B) described above, may serve this function. Alternatively or additionally, an extension such as extension 420 may also serve this function. The size of the groove (e.g., a width) may be slightly smaller than the size of the extension (e.g., a width) such that, when the electrical contact is inserted into a respective opening, the extension frictionally engages with the groove in the wall of the opening. This engagement holds the electrical contact in the opening, even when the assembly tool is withdrawn, which might otherwise pull the electrical contact out of the opening.

Once the electrical contacts are inserted into respective openings of the housing of the interposer, the electrical contacts may be locked in place by deforming portions of the housing adjacent the electrical contracts. In some embodiments, the housing may be deformed by heat staking. FIG. 5B is an isometric view of the illustrative interposer 400 of FIGS. 5A and 4A-4B with the electrical contacts locked into respective openings with heat staking, such as may occur at a later step of the illustrative manufacturing process in accordance with some embodiments. Heat staking may be performed by applying energy to a portion 520 of the housing 508 of the interposer 400 and deforming the portion of the housing to form a protuberance 522 over the base. For each of the electrical contacts, the respective portion 520 may be adjacent an edge of the respective opening 406 in which the electrical contact is inserted and adjacent the base 422 of the electrical contact 404. The deforming may cause a portion of the housing material to be displaced over the base and lock the electrical contact in the opening.

In some embodiments, the energy may be applied as heat to increase the temperature of portion 520 of the housing adjacent the base. Energy may be applied in other forms, however, such as ultrasonic energy. In implementations in which the housing is made of a thermoplastic material, applying heat may place the portion of the housing in a molten or softened state. In combination with applying heat, pressure may be applied to portion 520 to push material from the housing into a protuberance 522. In some examples, the pushing and the heating may be supplied by the same manufacturing tool, such as a heated punch (not shown). The motion and/or the heat supplied by the punch may be controlled to cause material from the housing to move down to form the protuberance 522, without disrupting the position of the electrical contact. In some embodiments, punching may entail moving a tip of the punch in the same direction as the inner wall 426 (e.g., in a vertical direction P) such that the protuberance 522 becomes a horizontally extending segment. In an example, the direction P may be parallel to the direction z of the electrical contact (see FIGS. 1, and 3C-3D). The punch may have a tip shaped to match the desired shape of the protuberance. Once the heat punch is removed, the deformed portion of the housing from heat staking may solidify to a new shape. In the example illustrated, the tip of the punch may be circular, which may result in the circular protrusion illustrated in FIGS. 5B-5C.

When the electrical contacts are locked into placed by deforming portions of the housing adjacent openings, for each such opening, a void may be created in the housing near the base of the electrical contact, representing the location from which material moved down to the top of the electrical contact 422. As shown in FIG. 5B, void 530 may be formed above the protuberance 522. An enlarged view of the void 530 is shown in FIG. 5C. The void may be defined between the top surface 526 of the protuberance 522 and top surface 528 of the housing 508, and beyond a portion 532 of the inner wall 426 of the opening 406. The portion 532 is part of a continuous surface along the inner wall 426 before the void is created. During heat staking, for example, the housing material in the portion where the void will be formed is pushed down to form the protuberance 522. Thus, the volume of the void may equal the volume of a portion of the protuberance inside the inner wall of the opening.

FIG. 5C illustrates an example interposer resulting from use of a punch when the cross-section of the punch used for heat staking is circular. As a result, the void 530 may be a partial cylindrical shape. The protuberance may have a partial disk shape, for example. In this example, the volume of the void is calculated as the area S1 multiplied by the depth of the void h1; the volume of the protuberance inside the inner wall is calculated as the area S2 multiplied by the thickness of the protuberance h2, where S1=S2. Although the void is shown to be a partial cylindrical shape, the void can be of any other shape depending on the cross-section of the punch used for heat staking. Further, the protuberance may have any suitable shape. Thus, the relationship between S1 and S2 as described above may also hold as the shapes of the void and the protuberance vary.

Returning to FIG. 5B, once an electrical contact is inserted and locked into place in a respective opening of the housing, the base 422 of the electrical contact 404 is captured between a shelf (such as 430, in FIG. 4B) and the protuberance 522. Although it is shown that the protuberance is formed at a different stage of the manufacturing process, the protuberance and the shelf within each of the plurality of openings may be monolithic and integral because both the protuberance and the shelf may be formed from the same materials of the housing.

In one or more manufacturing steps described in FIGS. 4A-4B and 5A-5C, the electrical contacts as described in FIGS. 3A-3D may be inserted and locked into respective openings of the housing 400. For example, the shelf in each of the openings of the housing may be parallel to the top and bottom surfaces of the housing to enable the base of a respective electrical contact in each opening to be disposed parallel to the top and bottom surfaces as well. That is, the plane that encompasses the base of the electrical contact (e.g., plane xy in FIG. 3C) may be positioned in parallel to and between the top surface and bottom surface of the housing of the interposer (e.g., surfaces 116, 118 of the housing 130 in FIG. 1). The first and second contact portions of each electrical contact may extend from the base of the electrical contact towards the top and bottom surfaces of the housing, respectively (shown in FIG. 3C). When an electrical contact is in an uncompressed state, the contact portions of the electrical contact will extend through the top and bottom surfaces of the housing and outside the housing (shown in FIG. 3C). This enables the electrical contact in the interposer to be in contact with the pads formed on the substrates that are pressed against the surfaces of the interposer. For example, with reference to FIG. 1, when in operation, the electrical contacts (112) of the interposer are in electrical contact with pads 108 of substrate 104 and/or pads 110 of substrate 106.

Such a configuration may sufficiently lock the electrical contacts in place such that, when the interposer is pressed between two substrates the contact portions deflect and exert a counter force based on spring energy stored in the contact portions. The electrical contact of FIG. 3B is shaded to show relative stress, and therefore spring energy, stored in an electrical contact when compressed. In this example, region 370 has the highest relative stress, with successive regions towards the base towards the tips having successively lower stress. Nonetheless, the U-shaped electrical contact enables storage of spring energy along substantial portions of the length of the electrical contact, leading to an appropriate contact force, even for a relatively small contact.

In the configuration of FIG. 5C, the base of the electrical contact is captured via a protuberance on one side, enabling the other side of the base to pivot within the opening if there is an imbalance of forces on the contact. Enabling such a motion may provide more reliable connections through the interposer. For example, an interposer with two opposing separable interfaces may have dual compression contacts with two beams extending from the base. An imbalance of forces may result from any of a number of causes, such as imprecision in the position of the contact points of each of the beams relative to the center of the interposer or imprecision in the location of the pads of the components mating to either or both of the separable interfaces. Such an imbalance may result in the contact force at one beam of the electrical contact being higher than at the other, which may lead to an unreliable connection at one or both of the interfaces. By enabling the contact to pivot in response to the imbalance, the imbalance may be reduced, reducing the chances of an unreliable connection.

Electrical contacts of other shapes may be locked into an interposer housing. FIG. 6A is a plan view of a blank with a plurality of electrical contacts stamped from a sheet of conductive metal, with a different shape than described above in connection with FIGS. 2-5C. A plurality of electrical contacts 604 may be stamped from a sheet of conductive metal 600, where the plurality electrical contacts are connected to a carrier 602. As shown in FIG. 6A, each electrical contact 604 may include a base 622 and a first contact portion 624 and a second contact portion 626. Each of the contact portions 624, 626 may include a beam extending from the base 622. For example, the contact portion 624 may include a beam 628, and the contact portion 626 may include beam 630, where beams 628, 630 both extend from the base 622. As shown in FIG. 6A, the base and the beams are integral for each of the electrical contacts because they are stamped from the same sheet of conductive metal. Alternatively, two or more parts of the electrical contacts (e.g., the beams of the first and second portions) may be separate and joined together (e.g., by welding, bonding etc.).

As further shown in FIG. 6A, each of the plurality of electrical contacts 604 may have an engagement feature. For example, the base of each of the plurality of electrical contacts 604 may have at least a projection, such as extension 620 that in this example extends in a direction perpendicular to an elongated axis of the first beam (e.g., 628, 630), represented by a centerline line AA. In the example shown in FIG. 6A, for each electrical contact, two extensions 620 extend from the base of the electrical contact in opposite directions. As described above, the projections alternatively or additionally may be in other shapes, such as a tab or a barb. For each electrical contact, the projection(s) may also be integral with the beams and the base as they may be stamped from the same sheet of conductive metal.

FIG. 6B illustrates a plurality of electrical contacts of FIG. 6A in an isometric view, in accordance with some embodiments. These contacts may be manufactured by forming the blank of FIG. 6A into a three-dimensional shape. In some embodiments, in each of the plurality of electrical contacts 604, the base 622 of the electrical contact may be formed into a U-shaped base having a radius of curvature in a plane perpendicular to a plane defining the sheet of conductive metal 600 (e.g., plane xy). As shown in FIG. 6B, a portion of the base of the electrical contact together with one beam that extends from the portion (e.g., 628) is bent away from the plane xy, such that the beam (e.g., 628) swings towards the other beam of the electrical contact (e.g., 630). In some embodiments, the electrical contact 604 is formed so that the distal ends of the contact portions of the electrical contact (e.g., 632, 634) may be aligned to each other.

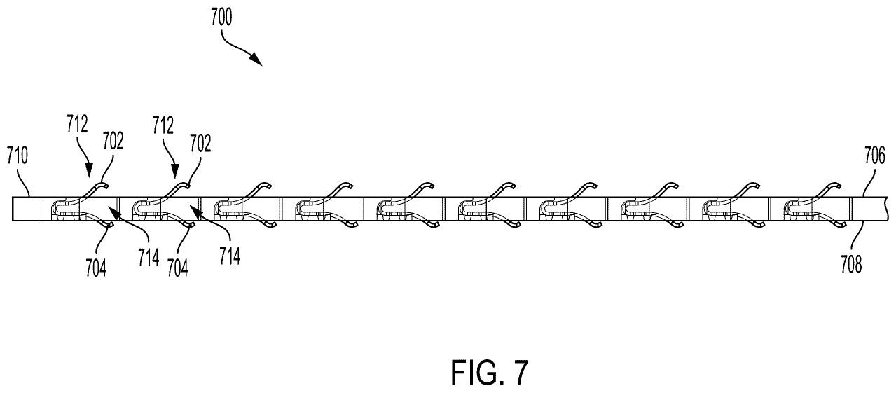

With further reference to FIG. 6B, the beams 628, 630 may be bent away from the plane xy to form an open jaw shape such that the distal ends 632, 634 of the contact portions of the electrical contact are separated and each on an opposite side of the plane xy. The bending of the beams of the contact portions 624, 626 enables the distal ends of the contact portions to extend through the top and bottom surfaces of the housing, respectively in an uncompressed state when the electrical contact is properly installed in a respective opening of the housing. This configuration is further illustrated in FIG. 7.

FIG. 7 is a side view of an illustrative interposer with a plurality of electrical contacts in respective openings in an interposer housing, in accordance with some embodiments. Interposer 700 may be at least a portion of the interposer 102 (of FIG. 1), for example.

Interposer 700 may include housing 710 with a plurality of openings 714 and a plurality of electrical contact 712 disposed in respective openings. In some embodiments, the electrical contacts 712 may include the electrical contacts shown in FIG. 6B. When the electrical contacts 712 are in an uncompressed state, the distal ends 702, 704 of the beams of each of the electrical contacts may extend through the top and bottom surfaces (706, 708) of the housing 710 of the interposer 700. Thus, the electrical contacts may be in electrical contact with the pads of the substrates that are pressed against the surface(s) of the interposer (see FIG. 1).

Returning to FIGS. 6A and 6B, for each of the plurality of electrical contacts 604, the beams 628, 630 may be tapered such that the beams have a smaller width at distal ends (e.g., 632, 634) than the width of the beams proximate to the base of the electrical contact 622. This configuration facilitates efficiently storing energy for the electrical contacts and result in a better electrical contact with pads of the substrates that are pressed with the interposer, as described in FIG. 1.

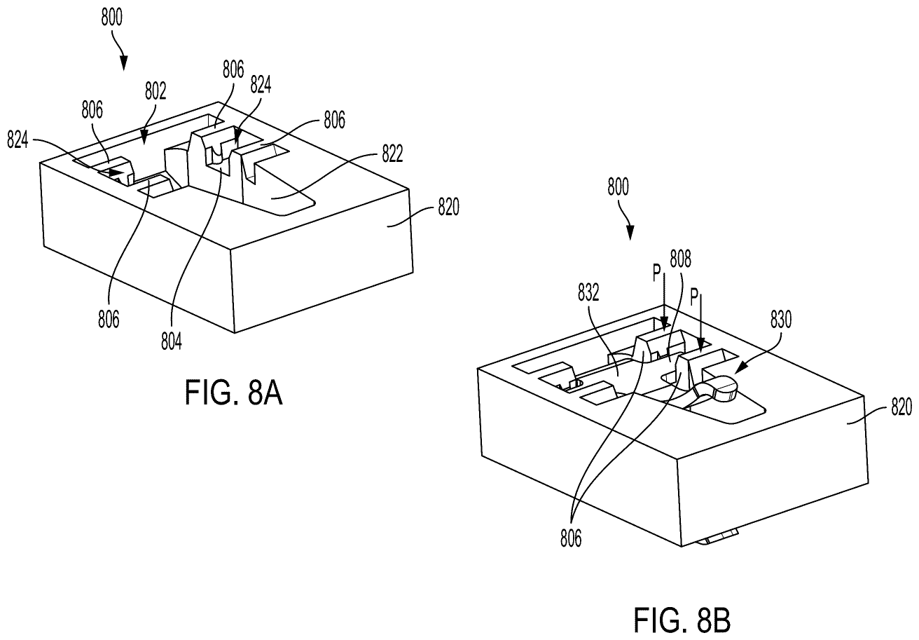

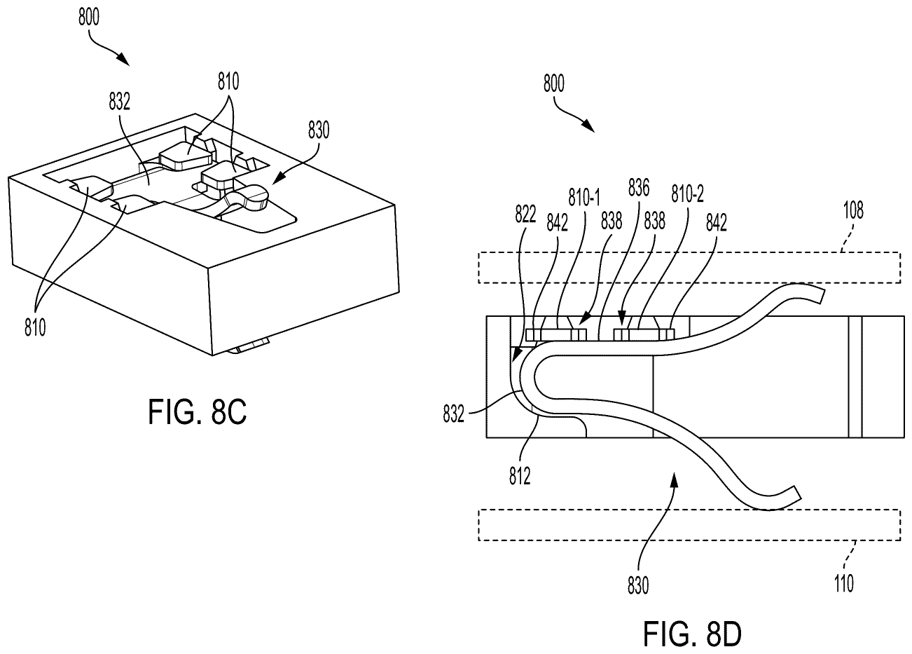

Electrical contacts, such as those shown in FIG. 6B may be locked in an interposer housing using similar techniques described in the present disclosure, such as those described above with reference to FIGS. 5A-5C. FIGS. 8A-8D illustrate a portion of an interposer with one opening and one electrical contact and further illustrate details of each of the electrical contacts and respective openings of the housing. FIG. 8A is an isometric view of an opening of an interposer housing, in accordance with some embodiments. In some examples, the opening of the interposer in FIG. 8A may be configured for an electrical contact (e.g. as shown in FIGS. 6A-6B) to be inserted therein. FIG. 8B is an isometric view of the opening of the illustrative interposer of FIG. 8A with an electrical contact pressed into place, in accordance with some embodiments. FIG. 8C is an isometric view of the opening of the illustrative interposer of FIGS. 8A-8B with the electrical contact locked into the opening with heat staking, in accordance with some embodiments. FIG. 8D is a side view of the electrical contact in the locked state shown in FIG. 8C, in accordance with some embodiments. The electrical contracts shown in FIGS. 8A-8D may be any of the electrical contacts shown in FIGS. 6A-6B.

Though a single opening is shown, as described above, it should be appreciated that multiple contacts may be processed in each operation. For example, a column or an array of contacts may be inserted in one operation. In some embodiments, the plurality of electrical contacts may be inserted into respective openings of the housing using a carrier. The carrier may be a support strip or any other shape. As shown in FIG. 6A, the carrier 602 and the plurality of electrical contacts 604 may be stamped from a sheet of conductive metal, for example, in a manner as shown in FIG. 3A. The carrier may be used to mount the plurality of electrical contacts into respective openings in the housing, in a similar manner as shown in FIG. 4A. For example, the arrangement of the plurality of electrical contacts in a sheet of conductive metal 600 may be the same as the plurality of openings in the housing of the interposer. This enables the insertion of the plurality of electrical contacts into their respective openings of the housing simultaneously. As similarly described in FIG. 4A above, the plurality of electrical contacts in FIG. 6A or 6B may be placed on top of the housing and aligned with respective openings in the housing, then severed from the carrier before being inserted or while being pressed into the respective openings.

With reference to FIGS. 8A-8D, a portion of an interposer 800 may be at least a portion of the interposer 700 of FIG. 7, for example. Thus, the housing 820 may be at least a portion of the housing 710 of FIG. 7. Opening 802 in the housing 800 may be one of the plurality of openings 714 of FIG. 7. In the example in FIGS. 8A-8D, an opening 802 may be bounded by one or more surfaces, such as one or more inner walls 822. In some embodiments, an inner wall may have one or more recessed areas (e.g., grooves), such as 824. Each groove may have one or more walls (e.g., vertical walls 806). A groove may also have a shelf (e.g., 804). Each of the one or more grooves 824 may receive a corresponding extension 808 of the base of the electrical contact. For example, as shown in FIG. 8B, electrical contact 830 (e.g., any of the electrical contacts shown in FIGS. 6A-6B) may be inserted into a respective opening 802, where one or more extensions 808 of the electrical contact 830 may extend into respective one or more grooves 824 to engage therewith. In the example shown, two extensions 808 of the base of an electrical contact 830 may extend perpendicular to the elongated axis of the electrical contact and in opposite directions. Thus, the corresponding groves 824 are disposed on opposite sides of the opening 802.

As shown in FIG. 8D, when pressed into a respective opening (e.g., 802), the one or more extensions 808 of the base 832 of electrical contact 830 may be rest on a respective shelf 812 in the opening. The shelf 812 may be integrated with the inner wall 822 in some embodiments. For example, the housing 820 may be molded with the plurality of openings and a respective shelf (or multiple shelves) in the inner wall of each opening. In some embodiments, the inner wall 822 of each opening may have a curved segment. The base 832 of the electrical contact 832 may also have a curved edge (e.g., a U-shape) to conform with the curved segment of the inner wall of the opening.

To create the state illustrated in FIG. 8B, an assembly tool may press the electrical contact 830 into a respective opening 802 of the housing. Having the extension(s) of the electrical contact engaging with the groove(s) in the inner wall may restrain rotation of the electrical contact inside the opening. Such engagement alternatively or additionally may retain the electrical contact such that it stays in the opening when the assembly tool is withdrawn. For example, the size of the groove 824 (e.g., the width) may be slightly smaller than the size (e.g., the width) of the projection 808 such that, when the electrical contact is inserted into a respective opening, the projection 808 frictionally engages with the groove 824 in the wall of the opening. This engagement holds the electrical contact in the opening even when the assembly tool is withdrawn.

Once an electrical contact is inserted into a respective opening of the housing of the interposer, the electrical contact may be locked into place by deforming one or more portions of the housing adjacent the electrical contract. In some embodiments, deforming may include moving a portion of the insulative housing to form a protrusion over a portion of the base of the electrical contact, such as by heat staking. As described above, heat staking may include applying energy near a portion of the housing adjacent the base 832 of the electrical contact 830 such as the vertical wall(s) 806. Heat staking may further include deforming the portion of the housing to form a protuberance 810 over the base of the electrical contact. Heat staking may be performed in a similar manner as described above in embodiments in FIGS. 5A-5C. As shown in FIG. 8B, heat staking may include increasing the temperature near the portion(s) 806 to place the portion(s) 806 of the housing in a softened state. Then, a punch may apply pressure to portion(s) 806 in direction P (e.g., a vertical direction z shown in FIG. 1). This pressure may cause the portion(s) 806 to be displaced over the extension 808 of the base of the electrical contact. Comparing FIG. 8B with FIG. 8C, heat staking causes the material in the portion(s) 806 to move down to form the protuberance(s) 810 to lock the electrical contact in the opening.

As shown in FIG. 8D, during heat staking, a void may be created in the opening when the material of the housing near the base of the electrical contact moves to be on top of the electrical contact 836. For example, void 838 may be formed between the top surface 840 of the housing and top surface 842 of the protuberance 810. Further, as shown in FIG. 8D, when the punching is performed in a vertical direction (e.g., z direction), the protuberance may be formed as horizontally extending segment. Once the heat staking tool is removed, the displaced material from the portion(s) 806 may solidify to the new shape. As shown in FIG. 8C, the protuberance may be a rectangle shape, but other shapes may also be possible.

Returning to FIG. 8D, once an electrical contact is inserted and locked into place in a respective opening of the housing, the extension 808 of the base of the electrical contact 832 is captured between a shelf 804 and the protuberance(s) 810 (e.g., 810-2, 810-2). Because the protuberance(s) is/are formed from the same material of the housing in the heat staking process, the protuberance(s) and the shelf within the opening are monolithic and integral. The housing may include one or more other features, including shelf 812 that interacts with one side of the U-shaped proximal portion of the electrical contact. Shelf 812, for example, may support one side of the electrical contact within the housing and/or may equalize the forces exerted by the contact portions of the electrical contact.

Having thus described several embodiments, it is to be appreciated various alterations, modifications, and improvements may readily occur to those skilled in the art. Such alterations, modifications, and improvements are intended to be within the spirit and scope of the invention.

It is shown in the various embodiments above that each electrical contact in a respective opening of the housing has two contact portions each having a contact portion that includes a beam extending through the top or bottom surfaces of the housing of the interposer. This configuration provides a dual-compression design. As another example of a possible variation, one of the contact portions of the electrical contact may not need to have an extended beam. For example, the two contact portions of an electrical contact may have different types of structure, with the first contact portion having an extended beam as described above and the second contact portion using a different contact mechanism. For example, the second contact portion may include a solder ball, which may lead to an interposer with one separable interface and a fixed interface which may enable the interposer to be soldered to a substrate.

As described above with reference to FIGS. 4A and 6A, the carrier (e.g., support strip) may be used to align multiple electrical contacts to respective openings of a housing simultaneously. As yet another example of a possible variation, any number of electrical contacts (e.g., one or more) may be inserted into one or more respective openings. The electrical contacts to be used with a single carrier may not be limited to any number or any particular arrangement. This provides flexibility in manufacturing an interposer with any number of electrical contacts. In other variations, different electrical contacts may be inserted to the same housing at different times. For example, multiple electrical contacts may be inserted and locked into a first row of openings in the housing of an interposer, followed by another group of electrical contacts being inserted and locked into a second row of openings.

As an example of another variation, FIG. 1 illustrates an interposer used to connect two printed circuit boards mounted in parallel. In other examples, an interposer as described herein may be used for other purposes. For example, an interposer as described herein may be used in a chip socket. In such a configuration, the contact points of a separable interface of the interposer may be arranged to align with pads on a surface of a semiconductor chip and the interposer may be used in connection with mechanical components that press the semiconductor chip against the separable interface. Alternatively, an interposer as described herein may be used as part of a cable termination. In such a configuration, the contact points of a separable interface of the interposer may be arranged to align with pads on a surface of a flat flexible cable (FFC) or a paddle card to which one or more cables are terminated.

As an example of another variation, FIG. 2 illustrates an interposer with parallel columns of electrical contacts, with each column having the same pattern of contacts. The columns are aligned such that the contacts form a square array. In other examples, some of the columns may have different patterns of contacts of adjacent columns may be shifted such that electrical contacts in one column are aligned with the space between contacts in adjacent columns.

Further, FIG. 2 illustrate an interposer with an array of electrical contacts organized in rows or columns. The contacts have elongated directions that make an acute angle with respect to the column direction. FIG. 6B illustrates an array with contacts having an elongated direction that is perpendicular to the column direction. Electrical contacts as illustrated in FIG. 2 may be aligned as shown in FIG. 6B and vice versa.

As an example of another possible variation, FIG. 3C illustrates an electrical contact with contact portions having distal tips bent back towards a central plane of the interposer such that the distal tips of the contact portions extend into the opening in the interposer housing, even when the electrical contact is in an uncompressed state. FIG. 7, in contrast, illustrates electrical contacts with some or all of the distal tips outside of the housing in an uncompressed state. In a variation, the distal ends of contacts as illustrated in FIG. 7 may be bent to be within the housing in an uncompressed state.

Variations of embodiments are described in this disclosure, which include, but are not limited to, the following examples:
A1. An interposer, comprising: an insulative member comprising a first surface, a second surface parallel to the first surface, and a plurality of openings through the insulative member, the insulative member further comprising a shelf and a protuberance within each the plurality of openings; and a plurality of electrical contacts disposed within respective openings of the plurality of openings, each electrical contact of the plurality of electrical contacts comprising a base, a first contact portion extending from the base toward the first surface and a second contact portion extending from the base toward the second surface. For each electrical contact of the plurality of electrical contacts, the base is captured between a shelf and a protuberance within a respective opening of the plurality of openings.
A2. The interposer of example A1, wherein the insulative member comprises, for each of the plurality of openings, a void adjacent the protuberance and between the first surface and a top surface of the protuberance.
A3. The interposer of example A2, wherein the protuberance of each of the plurality of opening of the insulative member is a horizontally extending segment.
A4. The interposer of example A1, wherein: each of the plurality of the plurality of openings comprises an inner surface; and each of the plurality of electrical contacts comprises a projection engaging the inner surface.
A5. The interposer of example A4, wherein: the inner surface of each of the plurality of the plurality of openings comprises a curved segment; the respective electrical contact in each of the plurality of openings comprises a curved edge following the curved segment of the inner surface the opening within which the respective electrical contact is disposed; and for each of the plurality of electrical contacts, the projection is configured to restrain rotation of the electrical contact within the respective opening.
A6. The interposer of example A4, wherein: the inner surface comprises a groove; and the projection extends into the groove.
A7. The interposer of example A6, wherein the projection comprises a barb.
A8. The interposer of example A6, wherein: the projection is a first projection; and each of the plurality of electrical contacts comprises a second projection, wherein the first projection and the second projection of each of the plurality of electrical contacts extends perpendicular to an elongated axis of the electrical contact and in opposite directions.
A9. The interposer of example A3, wherein a volume of the void defined between the first surface and the top surface of the protuberance and beyond a wall of the corresponding opening of the plurality of openings is same as a volume of a portion of the protuberance inside the wall of the corresponding opening.
A10. The interposer of example A1, wherein the first contact portion comprises a first beam configured to extend through the first surface in an uncompressed state.
A11. The interposer of example A10, wherein the second contact portion comprises a second beam configured to extend through the second surface in an uncompressed state.
A12. The interposer of example A1, wherein the shelf is parallel to the first surface and the second surface.
A13. The interposer of example A1, wherein the shelf and the protuberance within each the plurality of openings are monolithic and integral.
B1. An interposer, comprising: an insulative member comprising a first surface, a second surface parallel to the first surface, and a plurality of openings through the insulative member; and a plurality of electrical contacts disposed within respective openings of the plurality of openings, each electrical contact of the plurality of electrical contacts comprising a base, a first contact portion extending from the base toward the first surface and a second contact portion extending from the base toward the second surface. For each electrical contact of the plurality of electrical contacts: (1) the base of the electrical contact is between a first portion of the insulative member and a second portion of the insulative member; (2) the first portion of the insulative member is between the electrical contact and the first surface; (3) the second portion of the insulative member is between the electrical contact and the second surface; and (4) the insulative member comprises a void between the first portion and the first surface adjacent a respective opening of the plurality of openings in which the electrical contact is disposed.
B2. The interposer of example B1, wherein: the first portion is a protuberance; and the second portion is a shelf of the respective opening.
B3. The interposer of example B1, wherein: each of the plurality of openings comprises an inner surface; and each of the plurality of electrical contacts comprises a projection engaging the inner surface of a corresponding opening of the plurality of openings.
B4. The interposer of example B3, wherein: the inner surface of each of the plurality of openings comprises a curved segment; the respective electrical contact in each of the plurality of openings comprises a curved edge following the curved segment of the inner surface of the opening within which the respective electrical contact is disposed; and for each of the plurality of electrical contacts, the projection is configured to restrain rotation of the electrical contact within the respective opening.
B5. The interposer of example B3, wherein the projection comprises a barb.
B6. The interposer of example B5, wherein: the barb is a first barb; and each of the plurality of electrical contacts comprises a second barb.
B7. The interposer of example B3, wherein: the inner surface comprises a groove; and the projection comprises a tab extending into the groove.
B8. The interposer of example B2, wherein a volume of the void defined between the first surface and the top surface of the protuberance and beyond a wall of the corresponding opening of the plurality of openings is same as a volume of a portion of the protuberance inside the wall of the corresponding opening.
C1. An interposer, comprising: an insulative housing comprising: (1) a first surface and a second surface parallel to the first surface; and (2) a plurality of openings arranged in an array and extending between the first surface and the second surface, each of the plurality of openings being bounded by a surface and comprising a groove in the surface. The interposer also includes a plurality of electrical contacts, each disposed within a respective opening of the plurality of openings and comprising a U-shaped base, a first beam extending from the U-shaped base, a second beam extending from the U-shaped base and an extension extending from the electrical contact. For each of the plurality of electrical contacts: (1) the extension of the electrical contact extends into the groove of the respective opening; and (2) the electrical contact is heat staked within the respective opening.
C2. The interposer of example C1, wherein the first beam and the second beam bend away from each other in a direction perpendicular to the first surface and the second surface.
C3. The interposer of example C1, wherein for each of the plurality of electrical contacts, the U-shaped base, the extension, the first beam and the second beam are integral.
C4. The interposer of example C1, wherein the first beam and the second beam of the electrical contact are tapered.
C5. The interposer of example C1, wherein for each of the plurality of electrical contacts: the U-shaped base is disposed in a plane parallel to the first surface and the second surface; the first beam of the electrical contact is bent from a first portion of the U-shaped base of the electrical contact away from the plane in a first direction; and the second beam of the electrical contact is bent from a second portion of the U-shaped base of the electrical contact away from the plane in a second direction, opposite the first direction.
C6. The interposer of example C5, wherein for each of the plurality of electrical contacts a spacing within the plane between the distal end of the first beam and the distal end of the second beam of the electrical contact is smaller than a spacing between the first portion of the U-shaped base and the second portion of the U-shaped base.
C7. The interposer of example C1, wherein for each of the plurality of electrical contacts the U-shaped base of the electrical contact has a radius of curvature in a plane perpendicular to the first surface and the second surface.
C8. The interposer of example C7, wherein for each of the plurality of electrical contacts the extension of the electrical contact extends in a first direction perpendicular to an axis of elongation of the first beam.
C9. The interposer of example C8, wherein for each of the plurality of electrical contacts: the extension of the electrical contact is a first extension; and the electrical contract further comprises a second extension extending in a second direction opposite the first direction, and wherein the second extension is integral with the first beam, the second beam and the U-shaped base.
C10. The interposer of example C9, wherein for each of the plurality of electrical contacts the first and second extensions rest on respective shelves within the respective opening and are locked into place via heat staking.
D1. A method of manufacturing an interposer comprising a plurality of electrical contacts held within an insulative member comprising a plurality of openings, wherein the plurality of electrical contacts each comprises a base, a first contact portion extending from the base and a second contact portion extending from the base. The method comprises: inserting the plurality of electrical contacts into respective openings in the insulative member such that the base of each of the plurality of electrical contacts is adjacent a shelf within a respective opening; and deforming the insulative member adjacent each of the respective openings to form a protuberance that locks the base of each of the electrical contact in the respective opening between the protuberance and the shelf.
D2. The method of example D1, wherein deforming the insulative member comprises heat staking.
D3. The method of example D1, wherein inserting the plurality of electrical contacts into the respective openings in the insulative member comprises: aligning the plurality of electrical contacts with the respective openings in the insulative member, wherein the plurality of electrical contacts are integral with a carrier; severing the plurality of electrical contacts from the carrier; and pressing the plurality of electrical contacts into the respective openings in the insulative member.
D4. The method of example D3, further comprising: stamping the plurality of electrical contacts and the carrier from a sheet of conductive metal.
E1. A method for manufacturing an interposer, comprising: stamping at least an electrical contact in a sheet of conductive metal defining a plane, wherein the electrical contact comprises a base and a contact portion comprising a beam extending from the base; bending the base portion into a U-shape; bending the contact portion away from the plane; inserting the electrical contact with into an opening of a housing; and locking the base of the electrical contact into place by heat staking.
E2. The method of example E1, wherein: the electrical contact comprises an engagement feature; and inserting the electrical contact with into the opening of the housing comprises engaging the engagement feature with the housing.
E3. The method of example E1, wherein: the contact portion is a first contact portion; the electrical contact further comprises a second contact portion comprising a beam extending from the base; and the method further comprising bending the second contact portion away from the first contact portion such that a distal end of the first contact portion and a distal end of the second contact portion are separated.
E4. The method of example E2, wherein stamping the electrical contact comprises stamping the first and second contact portions with a taper.
E5. The method of example E1, wherein: the housing comprises a first surface and a second surface parallel to each other; the opening extends from the first surface to the second surface; and inserting the electrical contact into the opening of the housing comprises pressing an extension of the electrical contact in a groove in the opening so that the extension of the electrical contact rests on a shelf in the opening between the shelf in the opening and the first surface of the housing.
E6. The method of example E5, wherein locking the electrical contact comprises: applying energy to a portion of the housing adjacent the extension of the electrical contact to soften the portion; and pressing the portion of the housing to move materials thereof to form a protuberance between the extension of the electrical and the first surface of the housing and leaving a void between the protuberance and the first surface of the housing.
E7. The method of example E5, wherein applying energy to the portion of the housing comprises increasing the temperature of the portion to place the portion in a softened state.
E8. The method of example E5, wherein: the extension of the electrical contract is a first extension; the groove in the opening is a first groove; the shelf in the opening is a first shelf; and inserting the electrical contact into the opening of the housing comprises: pressing a second extension of the electrical contact in a second groove in the opening so that the second extension of the electrical contact rests on a second shelf in the opening between the second shelf in the opening and the first surface of the housing, wherein the first extension and the second extension extend from a centerline of the electrical contact in opposite directions.
E9. The method of example E8, wherein locking the electrical contact further comprises: applying energy to another portion of the housing adjacent the second extension of the electrical contact to soften the portion; and pressing the another portion of the housing adjacent the second extension to move materials thereof to form another protuberance between the second extension of the electrical and the first surface of the housing leaving another void between the another protuberance and the first surface of the housing.
E10. The method of example E5, wherein: stamping the electrical contact comprises stamping a plurality of electrical contacts including the electrical contact and a carrier in the sheet of conductive metal, each of the plurality of electrical contacts comprising an extension, wherein the carrier is connected to respective extensions of the plurality of electrical contacts.
E11. The method of example E9, wherein inserting the electrical contact into the opening of the housing comprises: using the carrier to align the plurality of electrical contacts with respective openings of a plurality of openings of the housing including the opening; severing the plurality of electrical contacts from the carrier; and for each of the plurality of electrical contacts, pressing the extension of the electrical contacts in a groove in a respective opening of the plurality of openings so that the extension of the electrical contact rests on a shelf in the respective opening between the shelf in the respective opening and the first surface of the housing.
E12. The method of example E10, wherein locking the base of the electrical contact into place comprises locking the plurality of electrical contacts into place by heat staking.
E13. The method of example E11, wherein the groove in each of the plurality of openings has a size smaller than a size of the extension of each of the electrical contacts so that the extension of each of the plurality of electrical contacts is temporarily captured in the groove in the respective opening when pressed.
F1. A method for manufacturing an interposer, comprising: stamping from a sheet of metal at least an electrical contact with a U-shaped base and a first contact portion comprising a beam extending from the U-shaped base and a second contact portion comprising a beam extending from the U-shaped base; bending the first contact portion and the second contact portion away from a plane encompassing the U-shaped base in opposite directions such that a distal end of the first contact portion and a distal end of the second contact portion are separated in a direction perpendicular to the plane; inserting at least the U-shape base into an opening of a housing; and locking the electrical contact into the opening by heat staking.
F2. The method of example F1, wherein at least a distal tip of the first beam and a distal tip of the second beam are protected inside the opening of the housing.
F3. The method of example F1, wherein inserting the U-shaped base in the opening of the housing comprises: placing the U-shaped base on a shelf in the wall of the opening.
F4. The method of example F2, wherein locking the electrical contact into the wall comprises: increasing a temperature near a portion of the housing adjacent the U-shaped base of the electrical contact to place the portion of the housing in a softened state; and pressing the portion of the housing to cause at least a portion of material of the housing to be displaced over the U-shaped base of the electrical contact so that the electrical contact is locked into the opening.
F5. The method of example F3, wherein inserting the U-shaped base into the opening of the housing comprises pressing the U-shaped base of the electrical contact into the opening with an assembly tool and engaging a barb extending from the U-shaped base of the electrical contact with the wall of the opening such that the electrical contact stays in the opening when the assembly tool is withdrawn.
F6. The method of example F1, wherein stamping the electrical contact comprises cutting a blank comprising the electrical contact and a support strip from the sheet of conductive metal.
F7. The method of example F6, further comprising severing the electrical contact from the support strip while pressing the U-shaped base of the electrical contact into the opening.
F8. The method of example F1, wherein: stamping at least an electrical contact from the sheet of metal comprises stamping a blank comprising a plurality of electrical contacts including the at least the electrical contact and at least a support strip from the sheet of conductive metal, wherein the support strip is connected to the plurality of electrical contacts.
F9. The method of example F8, further comprising: using the support strip to align the plurality of electrical contacts with respective openings of a plurality of openings of the housing; and severing the plurality of electrical contacts from the support strip while pressing the at least the U-shape based into the opening of the housing.
F10. The method of example F1, wherein stamping the electrical contact from the sheet of metal comprise cutting each of the beam of the first contact portion and the beam of the second contact portion of the electrical contact with a taper.

Terms signifying direction, such as “top,” “bottom,” “up,” “down,” “upwards” and “downwards,” were used in connection with some embodiments. These terms were used to signify direction based on the orientation of components illustrated or connection to another component, such as a surface of a printed circuit board to which a termination assembly is mounted. It should be understood that electronic components may be used in any suitable orientation. Accordingly, terms of direction should be understood to be relative, rather than fixed to a coordinate system perceived as unchanging, such as the earth's surface.

Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Also, circuits and modules depicted and described may be reordered in any order, and signals may be provided to enable reordering accordingly.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Also, the phraseology and terminology used herein are for the purpose of description and should not be regarded as limiting. The use of “including,” “comprising,” “having,” “containing,” or “involving,” and variations thereof herein, is meant to encompass the items listed thereafter (or equivalents thereof) and/or as additional items.

What is claimed is:

1. An interposer, comprising:
an insulative member comprising a first surface, a second surface parallel to the first surface, and a plurality of openings through the insulative member, the insulative member further comprising a shelf and a protuberance within each the plurality of openings; and
a plurality of electrical contacts disposed within respective openings of the plurality of openings, each electrical contact of the plurality of electrical contacts comprising a base, a first contact portion extending from the base toward the first surface and a second contact portion extending from the base toward the second surface,
wherein, for each electrical contact of the plurality of electrical contacts, the base is captured between a shelf and a protuberance within a respective opening of the plurality of openings.

2. The interposer of claim 1, wherein the insulative member comprises, for each of the plurality of openings, a void adjacent the protuberance and between the first surface and a top surface of the protuberance.

3. The interposer of claim 1, wherein:
each of the plurality of the plurality of openings comprises an inner surface; and
each of the plurality of electrical contacts comprises a projection engaging the inner surface.

4. The interposer of claim 3, wherein:
the inner surface of each of the plurality of the plurality of openings comprises a curved segment;
the respective electrical contact in each of the plurality of openings comprises a curved edge following the curved segment of the inner surface the opening within which the respective electrical contact is disposed; and
for each of the plurality of electrical contacts, the projection is configured to restrain rotation of the electrical contact within the respective opening.

5. The interposer of claim 3, wherein:
the inner surface comprises a groove; and
the projection extends into the groove.

6. The interposer of claim 2, wherein a volume of the void defined between the first surface and the top surface of the protuberance and beyond a wall of the corresponding opening of the plurality of openings is same as a volume of a portion of the protuberance inside the wall of the corresponding opening.

7. The interposer of claim 1, wherein:
the first contact portion comprises a first beam configured to extend through the first surface in an uncompressed state.

8. The interposer of claim 1, wherein the shelf and the protuberance within each the plurality of openings are monolithic and integral.

9. An interposer, comprising:
an insulative member comprising a first surface, a second surface parallel to the first surface, and a plurality of openings through the insulative member; and
a plurality of electrical contacts disposed within respective openings of the plurality of openings, each electrical contact of the plurality of electrical contacts comprising a base, a first contact portion extending from the base toward the first surface and a second contact portion extending from the base toward the second surface,
wherein, for each electrical contact of the plurality of electrical contacts:
the base of the electrical contact is between a first portion of the insulative member and a second portion of the insulative member;
the first portion of the insulative member is between the electrical contact and the first surface;
the second portion of the insulative member is between the electrical contact and the second surface; and
the insulative member comprises a void between the first portion and the first surface adjacent a respective opening of the plurality of openings in which the electrical contact is disposed.

10. The interposer of claim 9, wherein:
the first portion is a protuberance; and
the second portion is a shelf of the respective opening.

11. The interposer of claim 9, wherein:
each of the plurality of openings comprises an inner surface; and
each of the plurality of electrical contacts comprises a projection engaging the inner surface of a corresponding opening of the plurality of openings.

12. The interposer of claim 11, wherein:
the inner surface of each of the plurality of openings comprises a curved segment;
the respective electrical contact in each of the plurality of openings comprises a curved edge following the curved segment of the inner surface of the opening within which the respective electrical contact is disposed; and
for each of the plurality of electrical contacts, the projection is configured to restrain rotation of the electrical contact within the respective opening.

13. The interposer of claim 11, wherein:
the inner surface comprises a groove; and
the projection comprises a tab extending into the groove.

14. The interposer of claim 10, wherein a volume of the void defined between the first surface and the top surface of the protuberance and beyond a wall of the corresponding opening of the plurality of openings is same as a volume of a portion of the protuberance inside the wall of the corresponding opening.

15. An interposer, comprising:
an insulative housing comprising:
a first surface and a second surface parallel to the first surface;
a plurality of openings arranged in an array and extending between the first surface and the second surface, each of the plurality of openings being bounded by a surface and comprising a groove in the surface; and
a plurality of electrical contacts, each disposed within a respective opening of the plurality of openings and comprising a U-shaped base, a first beam extending from the U-shaped base, a second beam extending from the U-shaped base and an extension extending from the electrical contact, wherein, for each of the plurality of electrical contacts:
the extension of the electrical contact extends into the groove of the respective opening; and
the electrical contact is heat staked within the respective opening.

16. The interposer of claim 15, wherein the first beam and the second beam bend away from each other in a direction perpendicular to the first surface and the second surface.

17. The interposer of claim 15, wherein for each of the plurality of electrical contacts, the U-shaped base, the extension, the first beam and the second beam are integral.

18. The interposer of claim 15, wherein the first beam and the second beam of the electrical contact are tapered.

19. The interposer of claim 15, wherein for each of the plurality of electrical contacts the U-shaped base of the electrical contact has a radius of curvature in a plane perpendicular to the first surface and the second surface.

20. The interposer of claim 19, wherein for each of the plurality of electrical contacts the extension of the electrical contact extends in a first direction perpendicular to an axis of elongation of the first beam.

21. The interposer of claim 20, wherein for each of the plurality of electrical contacts:
the extension of the electrical contact is a first extension;
the electrical contract further comprises a second extension extending in a second direction opposite the first direction, and wherein the second extension is integral with the first beam, the second beam and the U-shaped base.

22. The interposer of claim 21, wherein for each of the plurality of electrical contacts the first and second extensions rest on respective shelves within the respective opening and are locked into place via heat staking.
